(19) United States
(12) Patent Application Publication
(10) Pub. No.: US 2024/0224552 A1
(43) Pub. Date: Jul. 4, 2024

(54) THIN-FILM SOLAR CELL ALLOWING FOR TRANSPARENCY AND METHOD FOR MANUFACTURING SAME

(71) Applicant: KOREA UNIVERSITY RESEARCH AND BUSINESS FOUNDATION, Seoul (KR)

(72) Inventors: Yongseok JUN, Seoul (KR); Yoonmook KANG, Seoul (KR); Chanyong LEE, Seoul (KR); Seungkyu KIM, Seoul (KR); Jongwon KO, Seoul (KR)

(73) Assignee: KOREA UNIVERSITY RESEARCH AND BUSINESS FOUNDATION, Seoul (KR)

(21) Appl. No.: 18/567,514

(22) PCT Filed: Apr. 15, 2022
(86) PCT No.: PCT/KR2022/005483

§ 371 Date: Dec. 6, 2023

(30) Foreign Application Priority Data
Apr. 16, 2021 (KR) 10-2021-0049553

(51) Int. Cl. H10K 30/82; H10K 30/50; H10K 30/88; H10K 39/00; H10K 71/00; H10K 71/20; H10K 85/50

(52) U.S. Cl. CPC H10K 30/82; H10K 30/50; H10K 30/88; H10K 39/601; H10K 71/231; H10K 71/621; H10K 85/50

(57) ABSTRACT

A thin-film solar cell allowing for transparency, according to an embodiment of the present invention, comprises: multiple first electrode layers disposed on the top portion of a glass substrate so as to be spaced apart from each other on the glass substrate and have a predetermined pattern; a lower end layer disposed below the first electrode layers; an upper end layer disposed between the first electrode layers and the lower end layer, and formed on the top surface of the lower end layer through a dry etching process by using the first electrode layers as masks; and a barrier layer disposed in an area of the top surface of the lower end layer other than an area in which the upper end layer is formed.

### TECHNICAL FIELD

The present invention relates to a thin-film solar cell allowing for transparency and a method for manufacturing the same.

The present invention is derived from research conducted as part of the new renewable energy core technology development (R&D) of the Ministry of Trade, Industry and Energy (Project No: 1415169068, project management institution: Korea Institute of Energy Technology Evaluation and Planning, research project name: development of easily expandable transparent solar cell platform, task performing institution: Korea University Industry-University Cooperation Foundation, research period: 2020.06.01-2021.05.31, contribution rate: 1/2).

Further, the present invention is derived from research conducted as part of a personal basic research (R&D) of the Ministry of Science and ICT (Project No: 1711120716, project management institution: National Research Foundation of Korea, research project name: manufacturing and analysis of intermediate interfacial layer for Si/perovskite heterojunction solar cell, task performing institution: Korea University Industry-University Cooperation Foundation, research period: 2020.09.01-2021.08.31, contribution rate: 1/2).

Meanwhile, there is no property interest of the Korean government in any aspect of the present invention.

### BACKGROUND ART

An element that converts energy of photons generated from the sun into electrical energy through the photoelectric effect is called a solar cell. A core material of the solar cell is a light absorbing layer that exhibits the photoelectric effect. Examples of the material include copper indium gallium selenide (CIGS), cadmium telluride (CdTe), a group III-V element composite material, a photoactive organic material, perovskite, and the like.

In the case of a general element such as a solar power plant or a building-mounted and building-integrated solar cell according to the related art, there are limitations that make it difficult to provide high transmittance properties, and translucent properties are not required for use. However, in recent years, as building windows and vehicle glasses are replaced with solar cells having translucent properties, a technology that may have effects such as securing of visibility and production of electrical energy at the same time has been spotlighted.

Meanwhile, a perovskite solar cell that uses perovskite as a material of a light absorbing layer is a type of thin film solar cells and has translucent properties and lightweight properties. The present invention may replace the building windows, the vehicle glasses, and the like, which require translucent properties, using the perovskite, and may be used as a power source for a wearable device because the solar cell includes flexible properties.

Further, in the present invention, an etching process is used as a main process to secure transparency, and etching is a process of removing a desired portion of a surface and may be roughly classified into physical etching and chemical etching. In detail, the chemical etching is classified into wet etching in which the surface is isotropically etched and dry etching in which the surface is anisotropically etched. The present invention provides a thin film solar cell considering transparency based on the drying etching using plasma, reactive ion etching (RIE), or the like, and a method of manufacturing the same.

### DETAILED DESCRIPTION OF THE INVENTION

### Technical Problem

Embodiments of the prevent invention provide a thin film solar cell considering transparency, in which an area of a light absorbing layer is freely selected and power generation efficiency and transparency may be simultaneously secured, and a method of manufacturing the same.

### Technical Solution

A thin film solar cell considering transparency according to the present invention includes a first electrode layer disposed on a substrate to have a preset pattern as the plurality of first electrode layers are spaced apart from each other on the substrate, a lower end layer disposed under the first electrode layer, an upper end layer disposed between the first electrode layer and the lower end layer and formed on an upper surface of the lower end layer through a dry etching process using the first electrode layer as a mask, and a barrier layer disposed an area of the upper surface of the lower end layer except for an area in which the upper end layer is formed.

Further, the thin film solar cell may further include a passivation layer that protects the upper end layer and the barrier layer from an external environment and blocks a leakage current.

Further, the upper end layer may include a hole transport layer and a light absorbing layer, the lower end layer may include the substrate, a second electrode layer, and an electron transport layer, and the light absorbing layer may include a perovskite material having a chemical formula of ABX3 (wherein A represents methylammonium (CH₃NH₃+), formamidinium (NH₂CHNH₂+) or cesium (Cs), B represents Pb or Sn, and X represents I, Br or Cl).

Further, the first electrode layer may include any one electrode material selected from the group consisting of a fluorine-doped tin oxide (FTO), an indium tin oxide (ITO), an aluminum-doped zinc oxide (AZO), an indium-doped zinc oxide (IZO), MoO₃, WO_{X}, a carbon nano tube (CNT), Au, Ag, Cu, Si, GaN, ZnO, SiO₂ and TiO₂.

Further, the electrode material may have any one structure selected from the group consisting of a micro rod, a nano rod, a micro wire, and a nano wire having a length greater than a width.

Further, the preset pattern may include a first pattern having a structure in which the plurality of first electrode layers having a length longer than a width are spaced a constant distance from each other, a second pattern having a structure in which the first electrode layer is disposed on the barrier layer to have a mesh network form, and a third pattern having a structure in which the first electrode layer and the barrier layer are arranged to form a grid pattern while intersecting each other.

Further, the upper end layer may be formed to have an inclined surface by adjusting an angle formed between the lower end layer and the ground during the dry etching process, and an angle of the inclined surface may be greater than −90° and smaller than 90°.

Further, the barrier layer may be formed during the dry etching process and include at least one inorganic material of PbI₂, PbO_{X}, PbBr₂, SnI₂, and SnBr₂, which are decomposition products of the light absorbing layer, and the barrier layer may suppress a leakage current by preventing formation of a shunt path due to contact between the hole transport layer and the electron transport layer.

Further, a color expressed by the barrier layer may be controlled according to a mixing ratio I/Br of I and Br among a composition of the light absorbing layer, the barrier layer may express yellow as the mixing ratio increases, and the barrier layer may express colorless as the mixing ratio decreases.

Further, the passivation layer may further include a plurality of light scattering particles.

Further, a light emitting diode (LED) light emitter may be disposed on an outer surface of a lower side of the substrate.

### Advantageous Effects of the Invention

According to a thin film solar cell considering transparency and a method of manufacturing the same according to embodiments of the present invention, an area of a light absorbing layer may be freely selected, and power generation efficiency and transparency may be simultaneously secured.

### DESCRIPTION OF THE DRAWINGS

FIGS. 1A to 1D are conceptual diagrams for describing a structure and a manufacturing process of a thin film solar cell considering transparency according to an embodiment of the present invention.

FIG. 2 is a conceptual diagram for describing a structure of a thin film solar cell considering transparency according to another embodiment of the present invention.

FIG. 3 is a conceptual diagram for describing a structure of a thin film solar cell considering transparency according to still another embodiment of the present invention.

FIG. 4A is a view illustrating an electrode formed in a first pattern in the thin film solar cell considering transparency according to the present invention, FIG. 4B is a view illustrating an electrode formed in a second pattern in the thin film solar cell considering transparency according to the present invention, FIG. 4C is a view illustrating an electrode formed in a third pattern in the thin film solar cell considering transparency according to the present invention, FIG. 4D is a view illustrating an electrode formed in a fourth pattern in the thin film solar cell considering transparency according to the present invention, and FIG. 4E is a view illustrating an electrode formed in a fifth pattern in the thin film solar cell considering transparency according to the present invention.

FIG. 5 is a flowchart illustrating a method of manufacturing a thin film solar cell considering transparency according to an embodiment of the present invention.

FIG. 6A is a picture illustrating a thin film solar cell manufactured according to comparative example 1, and FIG. 6B is a picture illustrating a thin film solar cell manufactured according to example 1.

FIG. 7A is a scanning electron microscope (SEM) image illustrating a surface and a cross section of the thin film solar cell manufactured according to comparative example 1, FIG. 7B is an SEM image illustrating a surface and a cross section of the thin film solar cell manufactured according to example 1, and FIG. 7C is an SEM image illustrating a cross section of a non-etched area (“B” in FIG. 7B) of the thin film solar cell manufactured according to example 1.

FIG. 8 is a graph depicting a difference between transmittances of example 1 and comparative example 1 of the present invention.

### BEST MODE

Hereinafter, an embodiment of the present invention will be described in detail with reference to the accompanying drawings.

In addition, in description of the present invention, when it is determined that the detailed description of widely known related configuration or function may make the subject matter of the present invention unclear, the detailed description will be omitted.

Embodiments of the present invention are provided to more completely describe the present invention to those skilled in the art, the following embodiments may be modified into various other forms, and the scope of the present invention is not limited to the following embodiments.

Rather, these embodiments are provided to make this disclosure be more thorough and complete and completely transfer the spirit of the present invention to those skilled in the art.

Further, in the following drawings, each component is exaggerated for convenience and clarity of description, and the same reference numerals refer to the same components on the drawings. In the present specification, a term “and/or” includes any one or all possible combinations of the listed items.

Terms used herein are used to describe specific embodiments, not to limit the present invention.

As used in the present specification, a singular form may include a plural form unless the context clearly indicates otherwise. Further, when used in the present specification, the terms “comprise” and/or “comprising” specify the presence of recited shapes, numbers, steps, actions, members, elements, and/or groups thereof, does not exclude the presence or addition of one or more other shapes, numbers, actions, members, and elements and/or groups.

The present invention relates to a thin film solar cell. In detail, the thin film solar cell is a thin film solar cell including one selected from a group III-V element composite material layer such as a copper indium gallium selenide (CIGS) layer, a cadmium telluride (CdTe) layer, and a gallium arsenide (GaAs) layer, a photoactive organic layer, a perovskite layer, and combinations thereof. In more detail, a perovskite-based thin film solar cell is proposed in which, among materials that are spotlighted as perovskite thin film solar cell materials having an ABX3 form, organic cations and metal cations including methylammonium (MA), formamidinium (FA), or cesium (Cs) are combined with A site, metal cations mixed with lead-tin (Pb—Sn) are combined with B site, and halogen elements mixed with iodine-bromine-chlorine (I—Br—Cl) are combined with C site.

Further, the present invention relates to a thin film solar cell considering transparency, in which a structure of a light absorbing layer is changed by a simplified etching process, an area of the light absorbing layer may be freely selected, and both power generation efficiency and transparency may be secured, and a method of manufacturing the same.

In the present invention, the thin film solar cell made of materials such as CIGS, CdTe, and perovskite, which have translucent properties, according to the related art, may overcome the lack of a practical use value due to a complementary relationship between light transmittance and light conversion efficiency, which is a problem occurring as a thickness or a chemical composition of the light absorbing layer is adjusted to improve the transparency.

That is, it is identified that the present invention may provide excellent transparency and light conversion properties by efficiently controlling light absorption and photocharge transfer while improving light transmittance through vertical structuring of the electrode, the hole transport layer, and the light absorbing layer of the thin film solar cell.

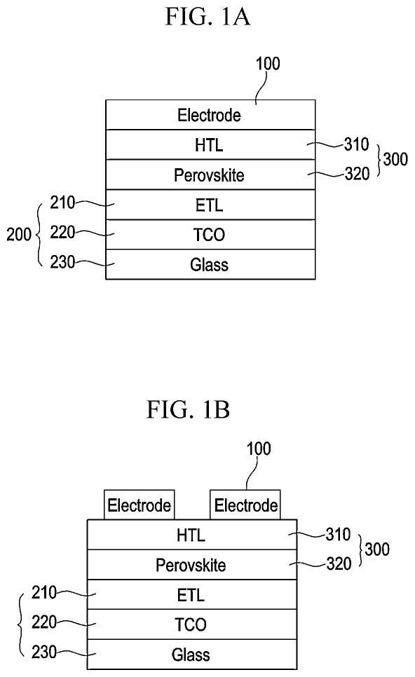

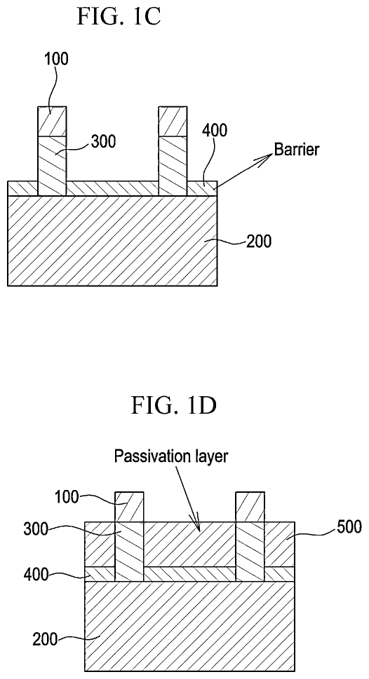

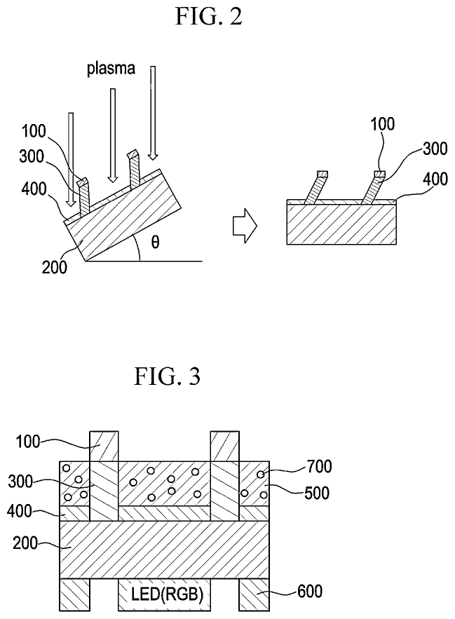

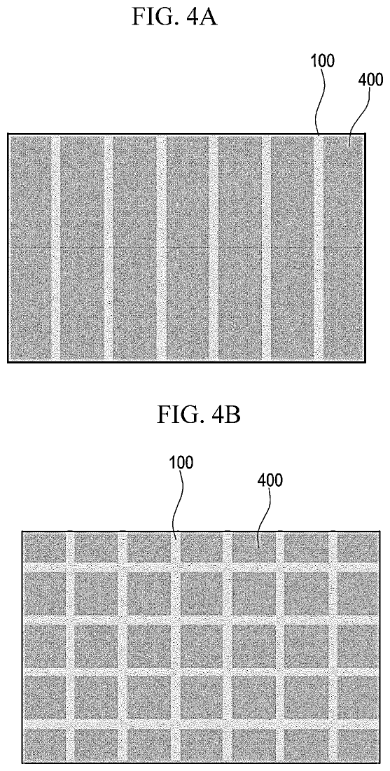

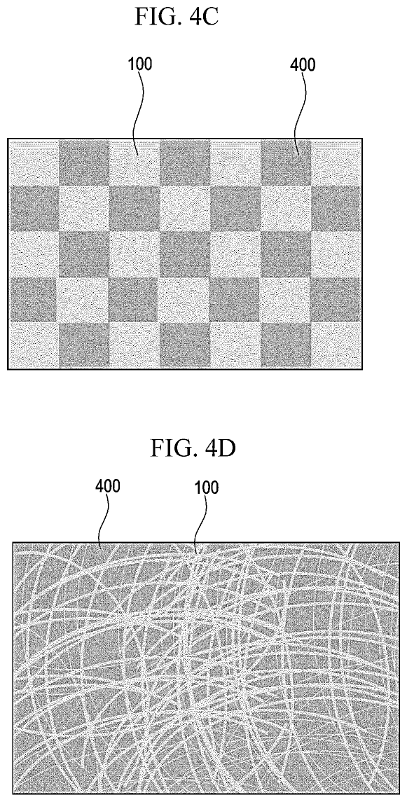

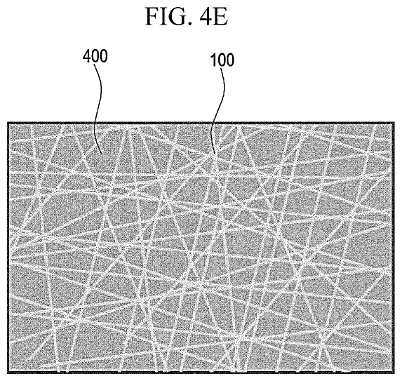

FIGS. 1A to 1D are conceptual diagrams for describing a structure and a manufacturing process of a thin film solar cell considering transparency according to an embodiment of the present invention, FIG. 2 is a conceptual diagram for describing a structure of a thin film solar cell considering transparency according to another embodiment of the present invention, FIG. 3 is a conceptual diagram for describing a structure of a thin film solar cell considering transparency according to still another embodiment of the present invention. FIG. 4A is a view illustrating an electrode formed in a first pattern in the thin film solar cell considering transparency according to the present invention, FIG. 4B is a view illustrating an electrode formed in a second pattern in the thin film solar cell considering transparency according to the present invention, FIG. 4C is a view illustrating an electrode formed in a third pattern in the thin film solar cell considering transparency according to the present invention, FIG. 4D is a view illustrating an electrode formed in a fourth pattern in the thin film solar cell considering transparency according to the present invention, and FIG. 4E is a view illustrating an electrode formed in a fifth pattern in the thin film solar cell considering transparency according to the present invention.

FIGS. 1A to 1D are conceptual diagrams for describing a structure and a manufacturing process of a thin film solar cell considering transparency according to an embodiment of the present invention. FIG. 1A is a view illustrating a thin film solar cell prepared in advance, FIG. 1B is a view illustrating a thin film solar cell having an etched electrode, and FIGS. 1C and 1D are views illustrating a thin film solar cell considering transparency according to the present invention.

First, as illustrated in FIG. 1A, to proceed with a process of manufacturing the thin film solar cell considering transparency according to the present invention, the thin film solar cell may be prepared in which a lower end layer 200 including a glass substrate 230, a second electrode layer 220, and an electron transport layer 210, an upper end layer 300 including a light absorbing layer 320 and a hole transport layer 310, and a first electrode layer 100 are sequentially laminated. The thin film solar cell is prepared in a solution process and a deposition process using vacuum equipment.

In detail, the thin film solar cell has a structure in which the second electrode layer 220 is formed on the glass substrate 230, the first electrode layer 100 is formed on the second electrode layer (220), and the light absorbing layer 320 is formed between the first electrode layer 100 and the second electrode layer 220.

The first electrode layer 100 and the second electrode layer 220 may generate electricity as electrons and holes generated by sunlight absorbed by the light absorbing layer 320 are collected.

In detail, the holes are collected in the first electrode layer 100 and the electrons are collected in the second electrode layer 220, so that respective electrodes may have opposite polarities.

The first electrode layer 100 and the second electrode layer 220 may include a metal electrode, an oxide-based transparent electrode, or the like. In detail, the first electrode layer 100 is a metal electrode including at least one electrode material selected from the group consisting of a fluorine-doped tin oxide (FTO), an indium tin oxide (ITO), an aluminum-doped zinc oxide (AZO), an indium-doped zinc oxide (IZO), MoO₃, WOX, a carbon nano tube (CNT), Au, Ag, Cu, Si, GaN, ZnO, SiO₂ and TiO₂, and combinations thereof. The second electrode layer 220 may be a transparent electrode made of the ITO or the FTO.

The light absorbing layer 320 is a thin film photoactive material having a single-layer or multi-layer structure and includes one layer selected from the group III-V element composite material layer such as the copper indium gallium selenide (CIGS) layer, the cadmium telluride (CdTe) layer, and the gallium arsenide (GaAs) layer, the photoactive organic layer, and the perovskite layer and combinations thereof.

In addition, in the present invention, the light absorbing layer 320 of the thin film solar cell may be the perovskite layer, and the hole transport layer 310 and the electron transport layer 210 may be arranged on an upper surface and a lower surface of the light absorbing layer 320, respectively. In this case, thicknesses of the light absorbing layer 320, the hole transport layer 310, and the electron transport layer 210 may be formed in a micrometer or nanometer scale.

The substrate 230 may be formed of a material as long as the material having physical properties capable of supporting a structure of the thin film solar cell such as metal or polymer and may be formed of a transparent material to allow sunlight to pass therethrough.

In detail, the substrate 230 may be formed of various materials such as glass, silicon, plastic, paper, and ceramic according to the purpose, and in the present invention, the substrate 230 may be implemented as a glass substrate.

Further, in the thin film solar cell, the thickness of the solar cell excluding the substrate 230 may be 10 m or less.

Referring to FIGS. 1B and 1C, the thin film solar cell considering transparency according to the embodiment of the present invention includes the first electrode layer 100, the lower end layer 200, the upper end layer 300, and a barrier layer 400.

As described above, the lower end layer 200 includes the electron transport layer 210, the second electrode layer 220, and the substrate 230, and the upper end layer 300 includes the hole transport layer 310 and the light absorbing layer 320.

First, the first electrode layer 100 are arranged on the substrate 230 to have a preset pattern as a plurality of first electrode layers 100 are spaced apart from each other on the substrate 230.

In this case, the first electrode layer 100 may be patterned through general wet etching and drying etching processes such as mask formation, etching, and mask removal.

Further, the first electrode layer 100 may include any one electrode material selected from the group consisting of the FTO, the ITO, the AZO, the IZO, the MoO₃, the WOX, the CNT, Au, Ag, Cu, Si, GaN, ZnO, SiO₂, and TiO₂.

In addition, in another embodiment, the electrode material may have any one structure selected from the group consisting of a nano-sized micro rod, a nano rod, a micro wire, and a nano wire having a length longer than a width.

In addition, as illustrated in FIGS. 4A and 4B, the preset pattern may be divided in the first to fifth patterns, and the first pattern, the second pattern, the third pattern, the fourth pattern, and the fifth pattern are illustrated in FIGS. 4A to 4E, respectively.

In detail, the preset pattern may be divided in the first pattern having a structure in which the plurality of first electrode layers 100 having a length longer than a width are spaced at a constant distance from each other, the second pattern having a structure in which the first electrode layer 100 is disposed on the barrier layer 400 in a mesh network form, and the third pattern having a structure in which the first electrode layer 100 and the barrier layer 400 are arranged to form a grid pattern while intersecting each other.

In addition, the preset pattern may further include the fourth pattern that is a structure in which the plurality of first electrode layers 100 having a length longer than a width and having a straight shape are arranged in a disorderly manner and the fifth pattern that is a structure in which the plurality of first electrode layers 100 having a length longer than a width and having a curved shape are arranged in a disorderly manner.

Next, the lower end layer 200 is disposed below the first electrode layer 100.

Further, the lower end layer 200 includes the electron transport layer 210, the second electrode layer 220, and the substrate 230. The electron transport layer 210 is a layer for collecting the electrons generated in the light absorbing layer 320 and moving the electrons to the second electrode layer 220 and may be implemented with any one material selected from phenyl-c61-butyric acid methyl ester (PCBM), TiO₂, SnO2 and ZnO. The substrate 230 is implemented as a glass substrate.

In the present invention, the lower end layer 200 may be implemented with TiO₂.

Next, the upper end layer 300 is disposed between the first electrode layer 100 and the lower end layer 200 and is formed on an upper surface of the lower end layer 200 through a dry etching process using the first electrode layer 100 as a mask.

In detail, according to the embodiment of the present invention, the dry etching process of the upper end layer 300 may be performed by a physical or chemical etching method and performed typically using plasma, ion, and reactive ion etching (RIE).

In the embodiment of the present invention, during the dry etching process using O₂ plasma, the lower end layer 200 is maintained parallel to the ground so that the upper end layer 300 is formed perpendicular to the lower end layer 200.

Further, as illustrated in FIG. 2, in another embodiment of the present invention, during the dry etching process using the O₂ plasma, an angle formed between the lower end layer 200 and the ground is adjusted so that the upper end layer 300 may be formed to have an inclined surface, and an angle of the inclined surface is greater than −90° and smaller than 90°.

In addition, in the present invention, the dry etching process using the O₂ plasma is not performed through a general process including the mask formation, the etching, and the mask removal, and the first electrode layer 100 may serve as both the mask and an electrode. Thus, since the mask formation and the mask removal are not required, the overall etching process may be simplified.

Further, the upper end layer 300 includes the hole transport layer 310 and the light absorbing layer 320, and the hole transport layer 310 is a layer that collects the holes generated in the light absorbing layer 320 and moves the holes to the first electrode layer 100 and is implemented with any material selected from spiro-OMeTAD, poly(3-hexythiopene) (P3HT), and polytriarylamine (PTAA).

In the present invention, the hole transport layer 310 may be implemented as spiro-OMeTAD.

In addition, a perovskite material used as the light absorbing layer 320 has a molecular structure of ABX3, and in the present invention, methylammonium (CH₃NH₃+), formamidinium (NH₂CHNH₂+), or cesium (Cs) may be used as A, lead (Pb) or tin (Sn) may be used as B, and a halogen substance such as bromine (Br), iodine (I), or chlorine (Cl) may be used as X.

In detail, the light absorbing layer 320 according to the present invention may be expressed based on Chemical Formula 1 in which lead (Pb) and tin (Sn) and iodine (I), bromine (Br), and chlorine (Cl) are combined.

ABX₃ [Chemical Formula 1]

Here, the A is an organic cation and a metal cation, the B is a metal element such as lead (Pb) and tin (Sn) or a combination thereof, and the X is a halogen element such as iodine (I), bromine (Br), or chlorine (Cl) or a combination thereof.

In addition, the light absorbing layer 320 is a layer formed between the first electrode layer 100 and the second electrode layer 220 to absorb transmitted sunlight and convert the absorbed sunlight into electrical energy and may be implemented as a thin film layer made of perovskite. Further, the light absorbing layer 320 may function as a photoelectric conversion layer that separates charges generated by absorbing the transmitted sunlight into the holes and the electrons to generate a current.

Next, the barrier layer 400 may be disposed in an area of the upper surface of the lower end layer 200 excluding an area in which the upper end layer 300 is formed.

In detail, the barrier layer 400 is formed during the drying etching process of the upper end layer 300 and may include one or more inorganic substances among PbI₂, PbO_{X}, PbBr₂, SnI₂, and SnBr₂ that are decomposition products of the light absorbing layer 320. In addition, the type and amount of inorganic materials included in the barrier layer 400 may change according to a composition of the light absorbing layer 320.

In more detail, a color expressed by the barrier layer 400 may be controlled according to a mixing ratio I/Br of I and Br among the composition of the light absorbing layer 320. As the mixing ratio increases, the color expresses yellow, and as the mixing ratio decreases, the color expresses colorless.

Further, the barrier layer 400 suppresses a leakage current by preventing formation of a shunt path due to contact between the hole transport layer 310 and the electron transport layer 210.

Accordingly, the barrier layer 400 according to the present invention is not formed through a separate process for forming a barrier and is formed simultaneously with the etching of the upper end layer 300 during the dry etching process of the upper end layer 300. Thus, the overall process of manufacturing a solar cell may be simplified.

Further, the barrier layer 400 according to the present invention may control the expressed color, and thus colors required in various industrial fields may be implemented.

Next, a structure of the thin film solar cell considering transparency according to still another embodiment of the present invention will be described with reference to FIGS. 1D and 3.

First, referring to FIG. 1D, the thin film solar cell considering transparency according to still another embodiment of the present invention may further include a passivation layer 500 that protects the upper end layer 300 and the barrier layer 400 from an external environment and blocks a leakage current.

The passivation layer 500 is formed to modularize a plurality of thin film solar cells considering transparency according to the embodiment of the present invention into a single color cell module and apply the modularized solar cell module to industrial sites.

Further, the passivation layer 500 may include a polymer-based material having high light transparency, such as polydimethysiloxane (PDMS) and polyimide (PI).

In addition, referring to FIG. 3, the passivation layer 500 may further include a plurality of light scattering particles 700.

In detail, the passivation layer 500 may be formed through a resin molding process based on a polymer resin, and the plurality of light scattering particles 700 may be added to the passivation layer 500 during the resin molding process.

The plurality of light scattering particles 700 may facilitate transmission of the sunlight to the light absorbing layer 320. In detail, the light scattering particles 700 may directly absorb the normal sunlight and then re-emit the sunlight or reflect the sunlight in a direction in which the light absorbing layer 320 is disposed.

Further, in the thin film solar cell considering transparency according to still another embodiment of the present invention, a light emitting diode (LED) light emitter 600 may be disposed on an outer surface of a lower side of the substrate 230.

The LED light emitter 600 may be a display element in the form of a unit element or a panel, and a position and a shape of the LED light emitter 600 may be adjusted according to a pattern of the first electrode layer 100.

Accordingly, the LED light emitter 600 does not interfere with or distort visibility of the display even when the LED light emitter 600 is coupled to a lower portion of the thin film solar cell.

Accordingly, in the thin film solar cell considering transparency according to still another embodiment of the present invention, the plurality of thin film solar cells may be connected to each other to expand the overall size in the form of a module or array and may be easily grafted onto a transparent support such as glass.

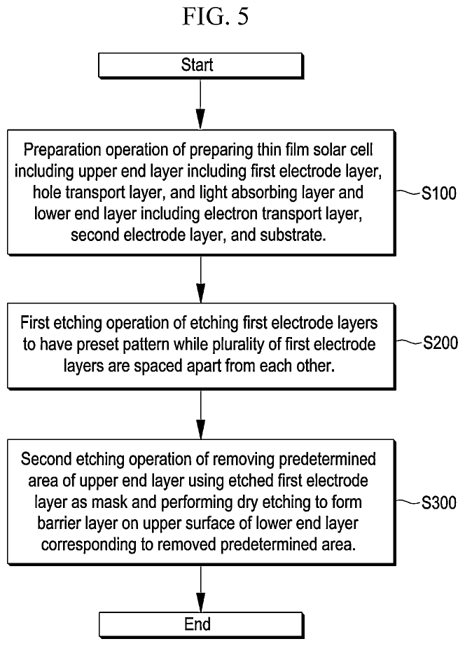

Hereinafter, a method of manufacturing the thin film solar cell considering transparency according to embodiments of the present invention will be described with reference to FIG. 5.

FIG. 5 is a flowchart illustrating a method of manufacturing a thin film solar cell considering transparency according to embodiments of the present invention.

Referring to FIG. 5, the method of manufacturing the thin film solar cell considering transparency according to embodiments of the present invention includes a preparation operation S100 of preparing a thin film solar cell including an upper end layer including a first electrode layer, a hole transport layer, and a light absorbing layer and a lower end layer including an electron transport layer, a second electrode layer, and a substrate, a first etching operation S200 of etching the first electrode layers to have a preset pattern while the plurality of first electrode layers are spaced apart from each other, and a second etching operation S300 of removing a predetermined area of the upper end layer using the etched first electrode layer as a mask and performing dry etching to form a barrier layer on an upper surface of the lower end layer corresponding to the removed predetermined area.

Further, the method of manufacturing the thin film solar cell considering transparency according to the embodiments of the present invention may further include a modularization operation S400 of forming a passivation layer that protects the etched upper end layer and the barrier layer from an external environment and blocks a leakage current.

In addition, the second etching operation S300 may further include adjusting an angle formed between the lower end layer and the ground during the dry etching process so that the etched upper end layer has an inclined surface.

In addition, the modularization operation S400 may further include adding a plurality of light scattering particles to a passivation layer and forming an LED light emitter 600 to an outer surface of a lower side of the substrate.

### <Example 1> Manufacturing of Thin Film Solar Cell Considering Transparency

Operation S100: prepare a thin film solar cell in which a glass substrate, an ITO electrode layer, a TiO₂ layer, a perovskite layer, a spiro-OMeTAD layer, and an Au electrode layer are sequentially laminated.

Operation S200: etch the plurality of Au electrode layers using O₂ plasma such that the Au electrodes may be spaced a constant distance from each other while having a length longer than a width.

Operation S300: remove predetermined areas of the spiro-OMeTAD layer and the perovskite layer using the etched Au electrode layer as a mask and perform etching using the O₂ plasma to form a barrier layer on an upper surface of the TiO₂ layer corresponding to the removed predetermined areas.

### <Comparative Example 1> Manufacturing of Thin Film Solar Cell

All processes were performed in the same manner as that of Example 1 except for operations S200 and S300.

### <Experimental Example 1> Evaluation of Macroscopic Properties of Thin Film Solar Cell

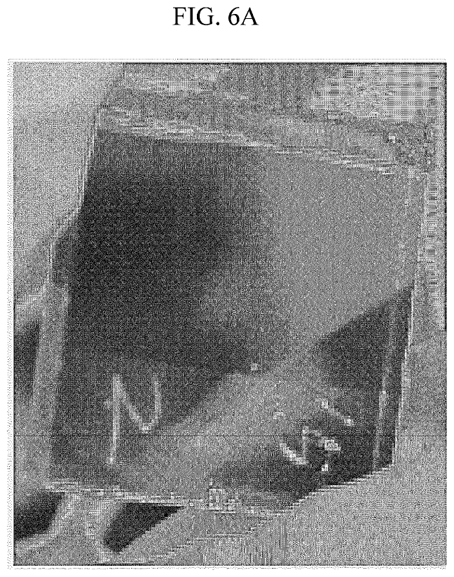

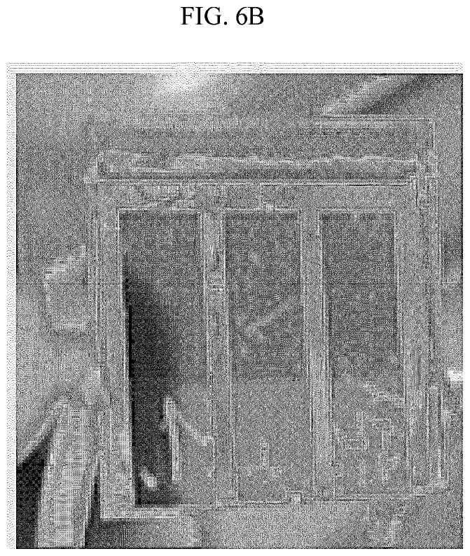

To identify macroscopic properties of the thin film solar cell manufactured according to the method of manufacturing the thin film solar cell considering transparency according to an embodiment of the present invention, the thin film solar cell manufactured through example 1 and comparative example 1 was photographed and illustrated in FIG. 6.

FIG. 6A is a picture illustrating a thin film solar cell manufactured according to comparative example 1, and FIG. 6B is a picture illustrating a thin film solar cell manufactured according to example 1.

In Example 1, the invented process was performed on a perovskite thin film solar cell that was an example of the thin film solar cell, and as in comparative example 1, the thin film solar cell on which the Au electrode was completely deposited was manufactured by dry-etching using O₂ plasma treatment.

As in FIG. 6B, a barrier layer including PbI2 formed as a portion not covered by the Au electrode was decomposed and translucency properties improved therethrough might be identified. Further, the barrier layer in FIG. 6B was observed to be yellow because the content of I in a mixing ratio of I and Br in a composition of a light absorbing layer was relatively high.

### <Experimental Example 2> Evaluation of Micro Structure of Thin Film Solar Cell

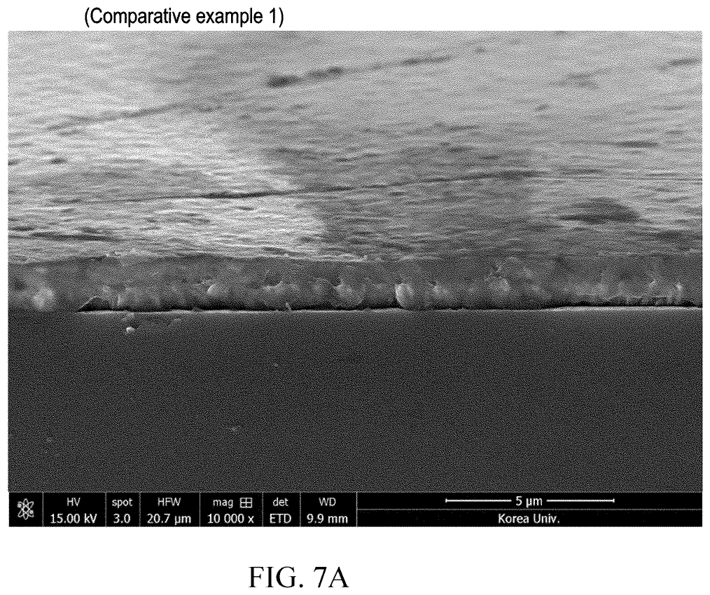

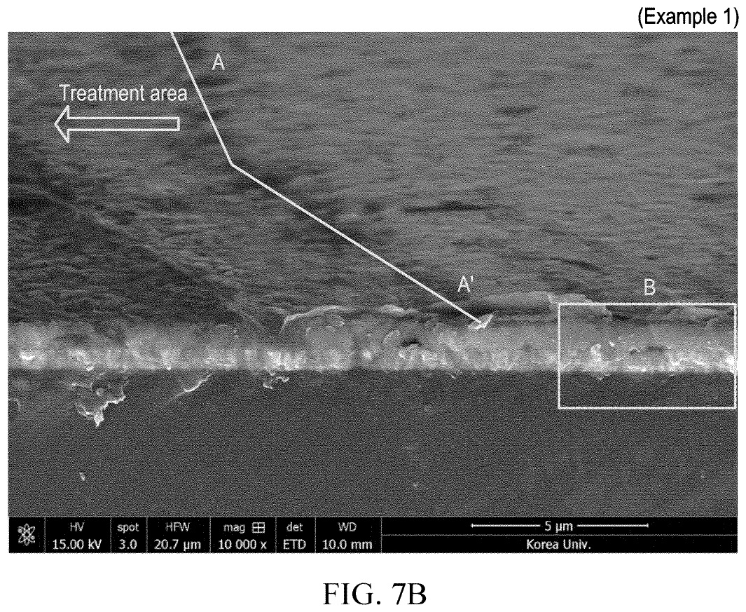

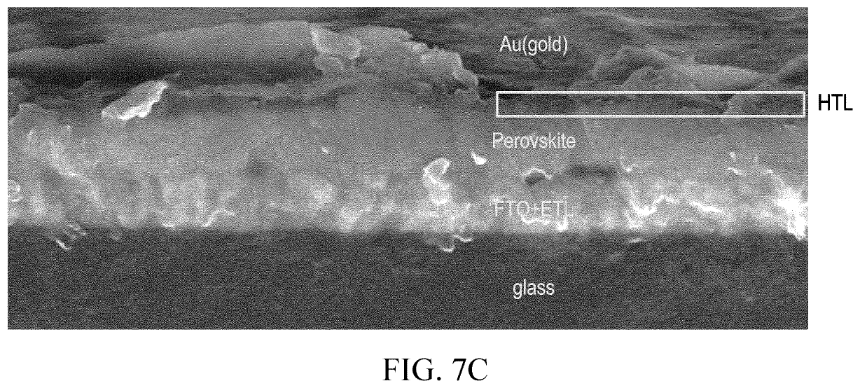

To compare evaluation of a micro structure of the thin film solar cell manufactured according to the method of manufacturing the thin film solar cell considering transparency according to the embodiment of the present invention, a surface and a cross-sectional micro structure of the thin film solar cell was identified through example 1 and comparative example 1 and was illustrated in FIG. 7.

FIG. 7A is a scanning electron microscope (SEM) image illustrating a surface and a cross section of the thin film solar cell manufactured according to comparative example 1, FIG. 7B is an SEM image illustrating a surface and a cross section of the thin film solar cell manufactured according to example 1, and FIG. 7C is an SEM image illustrating a cross section of a non-etched area (“B” in FIG. 7B) of the thin film solar cell manufactured according to example 1.

As illustrated in FIG. 7A, it might be identified in comparative example 1 that a structure was provided in which the ITO electrode layer, the TiO2 layer, the perovskite layer, the spiro-OMeTAD layer, and the Au electrode layer were sequentially laminated on the glass substrate.

Further, considering that a conductive material is brightly expressed due to SEM image characteristics, it might be identified that the surface of comparative example 1 was brightly displayed due to the laminated Au electrode layer.

Referring to FIGS. 7B to 7C, the SEM image in example 1 was divided into an etched area that was an area etched using O₂ plasma with respect to line A-A′ and a non-etched area that was an area not etched due to the Au electrode layer. In detail, it may be identified that the non-etched area appeared bright because a surface thereof was made of the conductive Au electrode layer, and the etched area appeared dark because the conductive spiro-OMeTAD layer and the conductive perovskite layer were removed, and at the same time, the non-conductive barrier layer was formed.

### <Experimental Example 3> Evaluation of Transparency of Thin Film Solar Cell

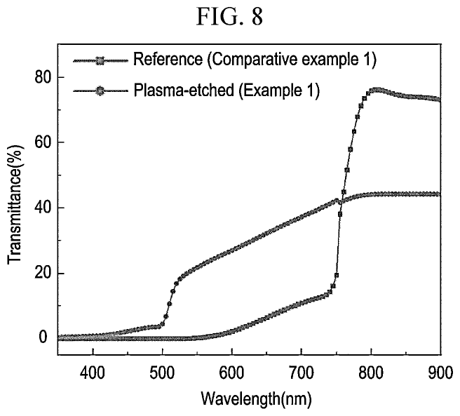

To compare evaluation of transparency of the thin film solar cell manufactured according to the method of manufacturing the thin film solar cell considering transparency according to the embodiment of the present invention, the transparency of the thin film solar cell was tested through example 1 and comparative example 1 and the result of the test was illustrated in FIG. 8.

FIG. 8 is a graph depicting a difference between transmittances of example 1 and comparative example 1 of the present invention.

Referring to FIG. 8, a significant difference between transmittances of example 1 and comparative example 1 might be identified in a visible light wavelength range of 400 nm to 700 nm. In detail, in the visible light wavelength range, the transmittance of example 1 was measured to be two to three times higher than that of comparative example 1 on average. From this result, it might be identified that as a partial area of the perovskite layer was removed through the etching process using O₂ plasma, an area of the light absorbing layer might be freely selected, and power generation efficiency and transparency might be secured at the same time.

Hereinabove, the thin film solar cell considering transparency and the method of manufacturing the same according to embodiments of the present invention have been described as specific embodiments. However, this is merely an example, and the present invention is not limited thereto and should be construed to have the widest scope according to the basic spirit disclosed herein. Those skilled in the art may implement a pattern of a shape not specified by combining and substituting the disclosed embodiments, but this also does not depart from the scope of the present invention. In addition, those skilled in the art may easily change or modify the embodiments disclosed based on the present specification, and it is obvious that these changes or modifications also belong to the scope of the present invention.

### DESCRIPTION OF REFERENCE NUMBERS

100: first electrode layer
200: lower end layer
300: upper end layer
400: barrier layer
500: passivation layer
600: LED light emitter
700: light scattering particles

1. A thin film solar cell considering transparency, comprising:
a first electrode layer disposed on a substrate to have a preset pattern as the plurality of first electrode layers are spaced apart from each other on the substrate;
a lower end layer disposed under the first electrode layer;
an upper end layer disposed between the first electrode layer and the lower end layer and formed on an upper surface of the lower end layer through a dry etching process using the first electrode layer as a mask; and
a barrier layer disposed an area of the upper surface of the lower end layer except for an area in which the upper end layer is formed.

2. The thin film solar cell of claim 1, further comprising:
a passivation layer configured to protect the upper end layer and the barrier layer from an external environment and block a leakage current.

3. The thin film solar cell of claim 2, wherein the upper end layer includes a hole transport layer and a light absorbing layer,
the lower end layer includes the substrate, a second electrode layer, and an electron transport layer, and
the light absorbing layer includes a perovskite material having a chemical formula of ABX₃ (wherein A represents methylammonium (CH₃NH₃+),
formamidinium (NH₂CHNH₂+) or cesium (Cs), B represents Pb or Sn, and X represents I, Br or Cl).

4. The thin film solar cell of claim 3, wherein the first electrode layer includes any one electrode material selected from the group consisting of a fluorine-doped tin oxide (FTO), an indium tin oxide (ITO), an aluminum-doped zinc oxide (AZO), an indium-doped zinc oxide (IZO), MoO₃, WO_{X}, a carbon nano tube (CNT), Au, Ag, Cu, Si, GaN, ZnO, SiO₂ and TiO₂.

5. The thin film solar cell of claim 4, wherein the electrode material has any one structure selected from the group consisting of a micro rod, a nano rod, a micro wire, and a nano wire having a length greater than a width.

6. The thin film solar cell of claim 5, wherein the preset pattern includes:
a first pattern having a structure in which the plurality of first electrode layers having a length longer than a width are spaced a constant distance from each other;
a second pattern having a structure in which the first electrode layer is disposed on the barrier layer to have a mesh network form; and
a third pattern having a structure in which the first electrode layer and the barrier layer are arranged to form a grid pattern while intersecting each other.

7. The thin film solar cell of claim 6, wherein the upper end layer is formed to have an inclined surface by adjusting an angle formed between the lower end layer and a ground during the dry etching process, and
an angle of the inclined surface is greater than −90° and smaller than 90°.

8. The thin film solar cell of claim 7, wherein the barrier layer is formed during the dry etching process and includes at least one inorganic material of PbI₂, PbO_{X}, PbBr₂, SnI₂, and SnBr₂, which are decomposition products of the light absorbing layer, and
the barrier layer suppresses the leakage current by preventing formation of a shunt path due to contact between the hole transport layer and the electron transport layer.

9. The thin film solar cell of claim 8, wherein a color expressed by the barrier layer is controlled according to a mixing ratio I/Br of I and Br among a composition of the light absorbing layer, the barrier layer expresses yellow as the mixing ratio increases, and the barrier layer expresses colorless as the mixing ratio decreases.

10. The thin film solar cell of claim 9, wherein the passivation layer further includes a plurality of light scattering particles.

11. The thin film solar cell of claim 10, wherein a light emitting diode (LED) light emitter is disposed on an outer surface of a lower side of the substrate.

12. A method of manufacturing a thin film solar cell considering transparency, the thin film solar cell including an upper end layer including a first electrode layer, a hole transport layer, and a light absorbing layer and a lower end layer including an electron transport layer, a second electrode layer, and a substrate, the method comprising:
a first etching operation of etching the first electrode layers to have a preset pattern while the plurality of first electrode layers are spaced apart from each other; and
a second etching operation of removing a predetermined area of the upper end layer using the etched first electrode layer as a mask and performing dry etching to form a barrier layer on an upper surface of the lower end layer corresponding to the removed predetermined area.

13. The method of claim 12, further comprising:
a modularization operation of forming a passivation layer that protects the etched upper end layer and the barrier layer from an external environment and blocks a leakage current.

14. The method of claim 13, wherein the second etching operation includes:
an operation in which the etched upper end layer has an inclined surface by adjusting an angle formed between the lower end layer and a ground during the dry etching process.

15. The method of claim 14, wherein the modularization operation includes:
adding a plurality of light scattering particles to the passivation layer; and
forming a light emitting diode (LED) light emitter on an outer surface of a lower side of the substrate.
